(19) United States
(12) Patent Application Publication
(10) Pub. No.: US 2018/0240997 A1
(43) Pub. Date: Aug. 23, 2018

(54) DOUBLE SIDE OLED DISPLAY ELEMENT AND MANUFACTURE METHOD THEREOF

(71) Applicant: WUHAN CHINA STAR OPTOELECTRONICE TECHNOLOGY CO. LTD., Wuhan City (CN)

(72) Inventor: Chao Xu, Wuhan City (CN)

(21) Appl. No.: 15/508,107

(22) PCT Filed: Dec. 29, 2016
(86) PCT No.: PCT/CN2016/113026

§ 371 Date: Mar. 2, 2017

(30) Foreign Application Priority Data
Dec. 15, 2016 (CN) 201611163394.8

(51) Int. Cl. H01L 51/52; H01L 51/56; H01L 51/00

(52) U.S. Cl. CPC H01L 51/5209; H01L 51/5218; H01L 51/5225; H01L 51/5253; H01L 51/56; H01L 27/3244; H01L 51/5234; H01L 2251/558; H01L 2251/308; H01L 2251/305; H01L 2251/301; H01L 51/0021

(57) ABSTRACT

Provided are a double Side OLED display element and a manufacture method thereof. The present invention provides a double side OLED display element, and by arranging the transparent anode and the reflective anode covering a portion of the transparent anode, and the transparent cathode and the reflective cathode covering a portion of the transparent cathode, the reflective anode and the reflective cathode completely covering the light emitting layer, together, and the reflective anode and the reflective cathode partially overlap at most in a vertical direction perpendicular to the array substrate so that the light emitted by the light emitting layer can emit out of one side of the transparent anode, and also can emit out of one side of the transparent cathode to realize the double side display and to solve the issues that the structure of the double side OLED display element of prior art is thicker and heavier.

### FIELD OF THE INVENTION

The present invention relates to a display technology field, and more particularly to a double Side OLED display element and a manufacture method thereof.

### BACKGROUND OF THE INVENTION

In the display technology field, the Liquid Crystal Display (LCD) and the Organic Light-Emitting Diode (OLED) have been gradually replaced the CRT (Cathode Ray Tube) displays.

The OLED display element possess properties of self-illumination, simple structure, ultra thin, fast response speed, wide view angle, low power consumption and bendability of realizing the flexible display, and therefore is considered as “dream display”. It has been favored by respective big display makers and has become the main selection of the third generation display element.

Specifically, the OLED display element generally comprises a substrate, an anode, a hole transporting layer, a light emitting layer, an electron transporting layer and a cathode. The light emission principle is that under certain voltage driving, the Electron and the Hole are respectively injected into the Electron Transporting Layer and the Electron Transporting Layer from the cathode and the anode, and then migrate to the Emitting layer, and bump into each other in the Emitting layer to form an exciton to excite the emitting molecule. The latter can illuminate after the radiative relaxation.

In comparison with the LCD element, the biggest superiority of the OLED display element is able to manufacture the element of large size, ultra-thin, flexibility, transparency and double side display.

As the forms of electronic products become more diversified, the double side display function becomes the main characteristic of the new generation display element, and particularly, some display element in the public places. However, most of the present double side OLED display devices are just to assemble the two independent, single side OLED display elements back to back to realize the double side display. The structure is relatively heavier, and the process is relatively complicated, and the manufacture cost is higher. It cannot conform to the flimsy and high cost-price value demands what the consumers expect.

### SUMMARY OF THE INVENTION

An objective of the present invention is to provide a double side display element, capable of solving the issues that the structure of the double side OLED display element manufactured by prior art is thicker and heavier, and the process is complicated, and the manufacture cost is higher.

Another objective of the present invention is to provide a manufacture method of a double side display element, and the structure of the double side OLED display element manufactured by the method is light and thin. The process is simple, and the manufacture method is relatively lower.

For realizing the aforesaid objectives, the present invention first provides a double side OLED display element, comprising an array substrate, a transparent anode covering the array substrate, a reflective anode covering a portion of the transparent anode, a hole transporting layer covering the reflective anode and the transparent anode, a light emitting layer covering the hole transporting layer, an electron transporting layer covering the light emitting layer, a transparent cathode covering the electron transporting layer, a reflective cathode covering a portion of the transparent cathode and a package layer covering the transparent cathode and the reflective cathode;

The reflective anode and the reflective cathode completely covering the light emitting layer, together, and the reflective anode and the reflective cathode partially overlap at most in a vertical direction perpendicular to the array substrate.

The reflective anode and the reflective cathode respectively cover two sides of the light emitting layer, and the reflective anode and the reflective cathode do not overlap in the vertical direction perpendicular to the array substrate.

The reflective anode covers ½-¾ of the light emitting layer, and a thickness is 20 nm-100 nm; the reflective cathode covers ¼-½ of the light emitting layer, and a thickness is 20 nm-100 nm.

The transparent anode utilizes a material having a high transmission rate, a high conductivity and a high work function; the reflective anode utilizes a material having a high reflectivity, a high conductivity and a high work function; the transparent cathode utilizes a material having a high transmission rate, a high conductivity and a low work function; the reflective cathode utilizes a material having a high reflectivity, a high conductivity and a low work function.

A material utilized for the transparent anode is indium tin oxide, indium zinc oxide, aluminum doped zinc oxide or indium zinc tin oxide; a material utilized for the reflective anode is silver, gold or platinum.

A material utilized for the transparent cathode is lanthanum hexaboride, or a stack combination of magnesium and silver; a material utilized for the reflective cathode is aluminum or magnesium.

The present invention further provides a manufacture method of a double side OLED display element, comprising steps of:

S1, providing an array substrate, and manufacturing a transparent anode covering the array substrate;

S2, providing a first mask, and manufacturing a reflective anode covering a portion of the transparent anode with the first mask;

S3, manufacturing a hole transporting layer covering the reflective anode and the transparent anode, a light emitting layer covering the hole transporting layer and an electron transporting layer covering the light emitting layer;

S4, manufacturing a transparent cathode covering the electron transporting layer;

S5, providing a second mask, and manufacturing a reflective cathode covering a portion of the transparent cathode with the second mask;

the reflective anode and the reflective cathode completely covering the light emitting layer, together, and the reflective anode and the reflective cathode partially overlap at most in a vertical direction perpendicular to the array substrate;

S6, implementing package on the transparent cathode and the reflective cathode to manufacture a package layer covering the transparent cathode and the reflective cathode.

The transparent anode utilizes a material having a high transmission rate, a high conductivity and a high work function; the reflective anode utilizes a material having a high reflectivity, a high conductivity and a high work function.

A material utilized for the transparent anode is indium tin oxide, indium zinc oxide, aluminum doped zinc oxide or indium zinc tin oxide; a material utilized for the reflective anode is silver, gold or platinum.

The transparent cathode utilizes a material having a high transmission rate, a high conductivity and a low work function; the reflective cathode utilizes a material having a high reflectivity, a high conductivity and a low work function.

A material utilized for the transparent cathode is lanthanum hexaboride, or a stack combination of magnesium and silver; a material utilized for the reflective cathode is aluminum or magnesium.

The present invention further provides a manufacture method of a double side OLED display element, comprising steps of:

S1, providing an array substrate, and manufacturing a transparent anode covering the array substrate;

S2, providing a first mask, and manufacturing a reflective anode covering a portion of the transparent anode with the first mask;

S3, sequentially manufacturing a hole transporting layer covering the reflective anode and the transparent anode, a light emitting layer covering the hole transporting layer and an electron transporting layer covering the light emitting layer;

S4, manufacturing a transparent cathode covering the electron transporting layer;

S5, providing a second mask, and manufacturing a reflective cathode covering a portion of the transparent cathode with the second mask;

the reflective anode and the reflective cathode completely covering the light emitting layer, together, and the reflective anode and the reflective cathode partially overlap at most in a vertical direction perpendicular to the array substrate;

S6, implementing package on the transparent cathode and the reflective cathode to manufacture a package layer covering the transparent cathode and the reflective cathode;

wherein the transparent anode utilizes a material having a high transmission rate, a high conductivity and a high work function; the reflective anode utilizes a material having a high reflectivity, a high conductivity and a high work function;

wherein the transparent cathode utilizes a material having a high transmission rate, a high conductivity and a low work function; the reflective cathode utilizes a material having a high reflectivity, a high conductivity and a low work function.

The benefits of the present invention are: the present invention provides a double side OLED display element, and by arranging the transparent anode and the reflective anode covering a portion of the transparent anode, and the transparent cathode and the reflective cathode covering a portion of the transparent cathode, the reflective anode and the reflective cathode completely covering the light emitting layer, together, and the reflective anode and the reflective cathode partially overlap at most in a vertical direction perpendicular to the array substrate so that the light emitted by the light emitting layer can emit out of one side of the transparent anode, and also can emit out of one side of the transparent cathode to realize the double side display and to solve the issues that the structure of the double side OLED display element manufactured by prior art is thicker and heavier, and the process is complicated, and the manufacture cost is higher. The present invention provides a manufacture method of a double side OLED display element. The reflective anode covering a portion of the transparent anode is manufactured with the first mask, and the reflective cathode covering a portion of the transparent cathode is manufactured with the second mask so that the light emitted by the light emitting layer can emit out of one side of the transparent anode, and also can emit out of one side of the transparent cathode to realize the double side display. The structure of the double side OLED display element manufactured by the method is light and thin. The process is simple, and the manufacture method is relatively lower.

### BRIEF DESCRIPTION OF THE DRAWINGS

In order to better understand the characteristics and technical aspect of the invention, please refer to the following detailed description of the present invention is concerned with the diagrams, however, provide reference to the accompanying drawings and description only and is not intended to be limiting of the invention.

In drawings,

FIG. 1 is a sectional structure diagram of a double side OLED display element according to the present invention;

FIG. 2 is a flowchart of a manufacture method of a double side OLED display element according to the present invention;

FIG. 3 is a diagram of step S2 of a manufacture method of a double side OLED display element according to the present invention;

FIG. 4 is a diagram of step S3 of a manufacture method of a double side OLED display element according to the present invention;

FIG. 5 is a diagram of step S4 of a manufacture method of a double side OLED display element according to the present invention;

FIG. 6 is a diagram of step S5 of a manufacture method of a double side OLED display element according to the present invention.

### DETAILED DESCRIPTION OF PREFERRED EMBODIMENTS

For better explaining the technical solution and the effect of the present invention, the present invention will be further described in detail with the accompanying drawings and the specific embodiments.

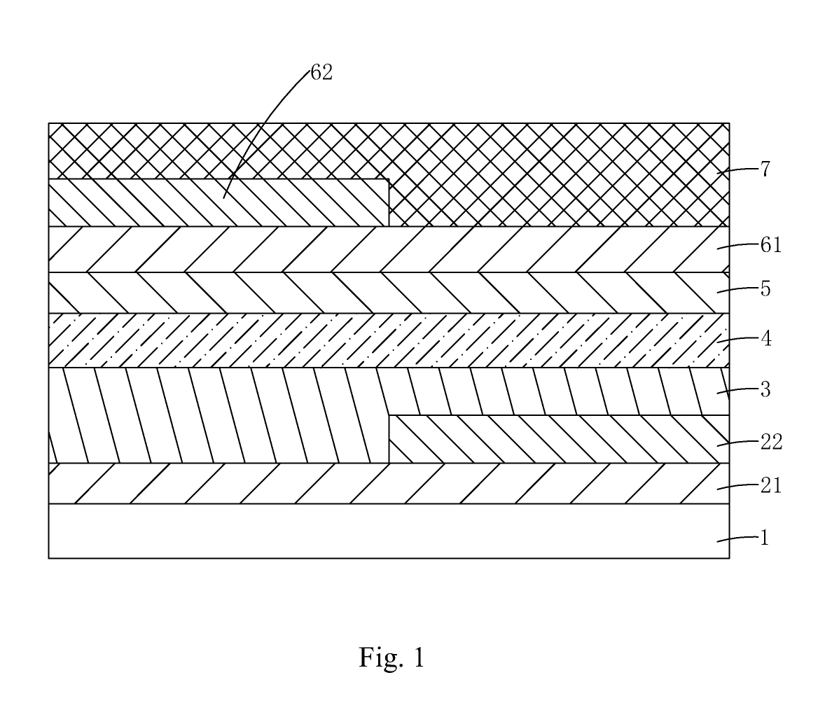

Please refer to FIG. 1. The present invention first provides a double side OLED display element, comprising an array substrate 1, a transparent anode 21 covering the array substrate 1, a reflective anode 22 covering a portion of the transparent anode 21, a hole transporting layer 3 covering the reflective anode 22 and the transparent anode 21, a light emitting layer 4 covering the hole transporting layer 3, an electron transporting layer 5 covering the light emitting layer 4, a transparent cathode 61 covering the electron transporting layer 5, a reflective cathode 62 covering a portion of the transparent cathode 61 and a package layer 7 covering the transparent cathode 61 and the reflective cathode 62.

The reflective anode 22 and the reflective cathode 62 completely cover the light emitting layer 4, together to prevent the light leakage; and the reflective anode 22 and the reflective cathode 62 partially overlap at most in a vertical direction perpendicular to the array substrate 1 to realize the double side display.

Furthermore, for achieving the best double side display result and promoting the illuminating efficiency, the reflective anode 22 and the reflective cathode 62 are respectively configured to cover two sides of the light emitting layer 4, and the reflective anode 22 and the reflective cathode 62 do not overlap in the vertical direction perpendicular to the array substrate 1; preferably, the reflective anode 22 covers ½-¾ of the light emitting layer 4, and a thickness is 20 nm-100 nm; the reflective cathode 62 covers ¼-½ of the light emitting layer 4, and a thickness is 20 nm-100 nm.

Specifically, the array substrate 1 comprises scan lines, data lines and a plurality of pixel drive unit circuit (including switch thin film transistors, drive thin film transistors and storage capacitors) aligned in array, which has no difference from the prior art. No detail description is conducted here.

The transparent anode 21 utilizes a material having a high transmission rate, a high conductivity and a higher work function, such as Indium Tin Oxide (ITO), Indium Zinc Oxide (IZO), Aluminum Doped Zinc Oxide (AZO) or Indium Zinc Tin Oxide (IZTO); the reflective anode 22 utilizes a material having a high reflectivity, a high conductivity and a higher work function, such as silver (Ag), gold (Au) or platinum (Pt).

The transparent cathode 61 utilizes a material having a high transmission rate, a high conductivity and a lower work function, such as lanthanum hexaboride (LaB6), or a stack combination of magnesium and silver (Mg/Ag); the reflective cathode 62 utilizes a material having a high reflectivity, a high conductivity and a lower work function, such as aluminum (Al) or magnesium (Mg).

The package layer 7 utilizes a glass package or a thin film package.

The working process of the OLED display element is: under certain voltage driving, the electron migrates from the transparent cathode 61 and the reflective cathode 62 to the light emitting layer 4 through the electron transporting layer 5, and the hole migrates from the transparent anode 21 and the reflective anode 22 to the light emitting layer 4 through the hole transporting layer 3, and electron and the hole bump into each other in the light emitting layer 4 to form an exciton to excite the emitting molecule in the light emitting layer 4, and the light emitting layer 4 emits the visible light; the reflective anode 22 reflects the light emitted by the light emitting layer 4 to one side of the transparent anode 61 and is emitted out, and the reflective cathode 62 reflects the light emitted by the light emitting layer 4 to one side of the transparent anode 21 and is emitted out to realize the double side display.

In comparison with prior art of assembling two independent, single side OLED display elements back to back to realize the double side display, the structure of the double side OLED display element of the present invention is light and thin. The process is simple, and the manufacture method is relatively lower.

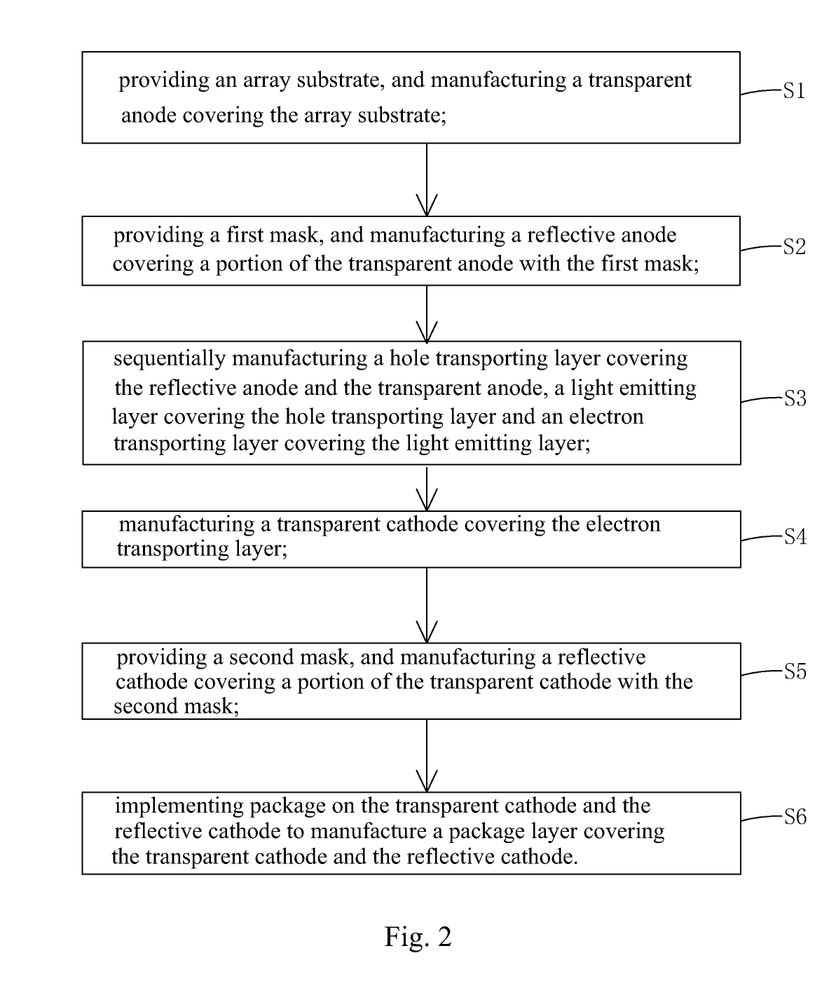

Please refer from FIG. 2 to FIG. 6 with combination of FIG. 1. The present invention further provides a manufacture method of a double side OLED display element, comprising steps of:

S1, providing an array substrate 1, and utilizing a process of sputter, evaporation, spin coating or printing for manufacturing a transparent anode 21 covering the array substrate 1;

Specifically, the array substrate 1 comprises scan lines, data lines and a plurality of pixel drive unit circuit (including switch thin film transistors, drive thin film transistors and storage capacitors) aligned in array, which has no difference from the prior art. No detail description is conducted here.

The transparent anode 21 utilizes a material having a high transmission rate, a high conductivity and a higher work function, such as ITO, IZO, AZO and IZTO.

S2, as shown in FIG. 3, providing a first mask (not shown), and implementing evaporation with the first mask for manufacturing a reflective anode 22 covering a portion of the transparent anode 21.

Specifically, the reflective anode 22 utilizes a material having a high reflectivity, a high conductivity and a higher work function, such as Ag, Au or Pt.

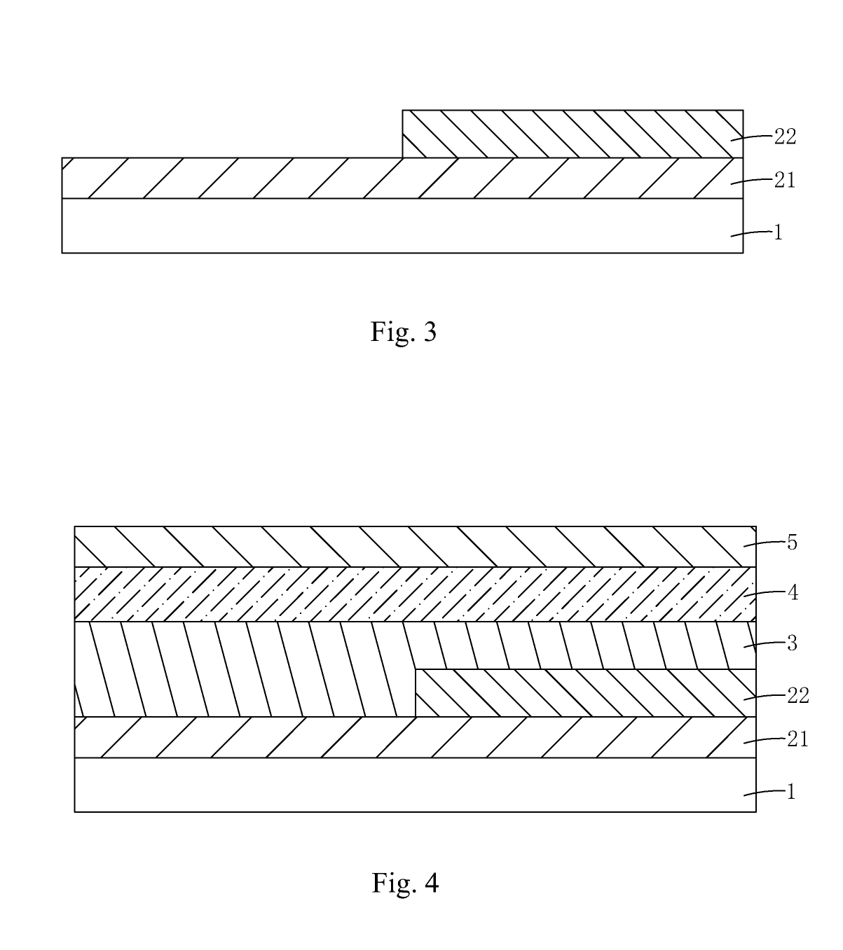

S3, as shown in FIG. 4, utilizing a process of sputter, evaporation, spin coating or printing for sequentially manufacturing a hole transporting layer 3 covering the reflective anode 22 and the transparent anode 21, a light emitting layer 4 covering the hole transporting layer 3 and an electron transporting layer 5 covering the light emitting layer 4.

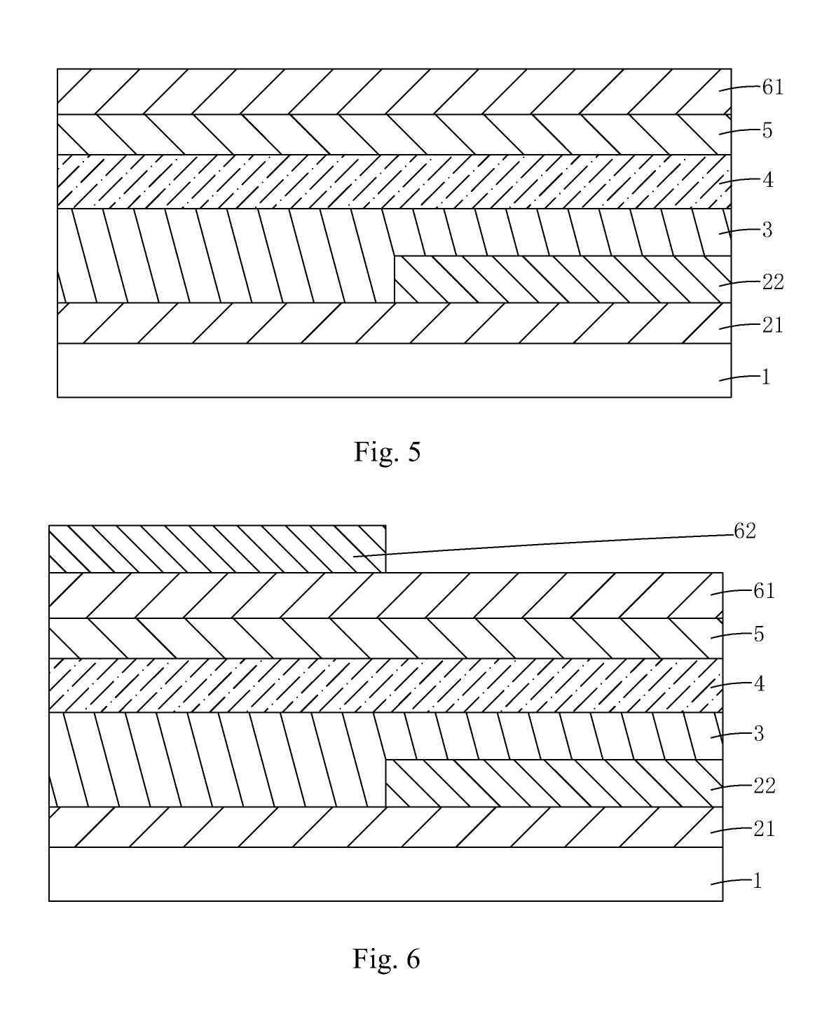

S4, as shown in FIG. 5, utilizing a process of sputter, evaporation, spin coating or printing for manufacturing a transparent cathode 61 covering the electron transporting layer 5.

Specifically, the transparent cathode 61 utilizes a material having a high transmission rate, a high conductivity and a lower work function, such as LaB6 or Mg/Ag.

S5, as shown in FIG. 6, providing a second mask (not shown), and implementing evaporation with the second mask for manufacturing a reflective cathode 62 covering a portion of the transparent cathode 61.

Significantly, the reflective anode 22 and the reflective cathode 62 completely cover the light emitting layer 4, together to prevent the light leakage; and the reflective anode 22 and the reflective cathode 62 partially overlap at most in a vertical direction perpendicular to the array substrate 1 to realize the double side display. Furthermore, for achieving the best double side display result and promoting the illuminating efficiency, the reflective anode 22 and the reflective cathode 62 are respectively configured to cover two sides of the light emitting layer 4, and the reflective anode 22 and the reflective cathode 62 do not overlap in the vertical direction perpendicular to the array substrate 1; preferably, the reflective anode 22 covers ½-¾ of the light emitting layer 4, and a thickness is 20 nm-100 nm; the reflective cathode 62 covers ¼-½ of the light emitting layer 4, and a thickness is 20 nm-100 nm.

Specifically, the reflective cathode 61 utilizes a material having a high reflectivity, a high conductivity and a lower work function, such as Al or Mg.

S6, referring to FIG. 1, implementing package on the transparent cathode 61 and the reflective cathode 62 to manufacture a package layer 7 covering the transparent cathode 61 and the reflective cathode 62.

Specifically, the package layer 7 utilizes a glass package or a thin film package.

Thus, the manufacture of the double side OLED display element is accomplished.

In the aforesaid manufacture method of the double side OLED display element, the reflective anode 22 covering a portion of the transparent anode 21 is manufactured with the first mask, and the reflective cathode 62 covering a portion of the transparent cathode 61 is manufactured with the second mask so that the reflective anode 22 can reflect the light emitted by the light emitting layer 4 to one side of the transparent anode 61 to be emitted out, and the reflective cathode 62 can reflect the light emitted by the light emitting layer 4 to one side of the transparent cathode 21 to be emitted out to realize the double side display. The structure of the double side OLED display element manufactured by the method is light and thin. The process is simple, and the manufacture method is relatively lower.

In conclusion, in the double side OLED display element of the present invention, by arranging the transparent anode and the reflective anode covering a portion of the transparent anode, and the transparent cathode and the reflective cathode covering a portion of the transparent cathode, the reflective anode and the reflective cathode completely covering the light emitting layer, together, and the reflective anode and the reflective cathode partially overlap at most in a vertical direction perpendicular to the array substrate so that the light emitted by the light emitting layer can emit out of one side of the transparent anode, and also can emit out of one side of the transparent cathode to realize the double side display and to solve the issues that the structure of the double side OLED display element manufactured by prior art is thicker and heavier, and the process is complicated, and the manufacture cost is higher. The present invention provides a manufacture method of a double side OLED display element. The reflective anode covering a portion of the transparent anode is manufactured with the first mask, and the reflective cathode covering a portion of the transparent cathode is manufactured with the second mask so that the light emitted by the light emitting layer can emit out of one side of the transparent anode, and also can emit out of one side of the transparent cathode to realize the double side display. The structure of the double side OLED display element manufactured by the method is light and thin. The process is simple, and the manufacture method is relatively lower.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A double side OLED display element, comprising an array substrate, a transparent anode covering the array substrate, a reflective anode covering a portion of the transparent anode, a hole transporting layer covering the reflective anode and the transparent anode, a light emitting layer covering the hole transporting layer, an electron transporting layer covering the light emitting layer, a transparent cathode covering the electron transporting layer, a reflective cathode covering a portion of the transparent cathode and a package layer covering the transparent cathode and the reflective cathode;
The reflective anode and the reflective cathode completely covering the light emitting layer, together, and the reflective anode and the reflective cathode partially overlap at most in a vertical direction perpendicular to the array substrate.

2. The double side OLED display element according to claim 1, wherein the reflective anode and the reflective cathode respectively cover two sides of the light emitting layer, and the reflective anode and the reflective cathode do not overlap in the vertical direction perpendicular to the array substrate.

3. The double side OLED display element according to claim 2, wherein the reflective anode covers ½-¾ of the light emitting layer, and a thickness is 20 nm-100 nm; the reflective cathode covers ¼-½ of the light emitting layer, and a thickness is 20 nm-100 nm.

4. The double side OLED display element according to claim 1, wherein the transparent anode utilizes a material having a high transmission rate, a high conductivity and a high work function; the reflective anode utilizes a material having a high reflectivity, a high conductivity and a high work function; the transparent cathode utilizes a material having a high transmission rate, a high conductivity and a low work function; the reflective cathode utilizes a material having a high reflectivity, a high conductivity and a low work function.

5. The double side OLED display element according to claim 4, wherein a material utilized for the transparent anode is indium tin oxide, indium zinc oxide, aluminum doped zinc oxide or indium zinc tin oxide; a material utilized for the reflective anode is silver, gold or platinum; a material utilized for the transparent cathode is lanthanum hexaboride, or a stack combination of magnesium and silver; a material utilized for the reflective cathode is aluminum or magnesium.

6. A manufacture method of a double side OLED display element, comprising steps of:
S1, providing an array substrate, and manufacturing a transparent anode covering the array substrate;
S2, providing a first mask, and manufacturing a reflective anode covering a portion of the transparent anode with the first mask;
S3, sequentially manufacturing a hole transporting layer covering the reflective anode and the transparent anode, a light emitting layer covering the hole transporting layer and an electron transporting layer covering the light emitting layer;
S4, manufacturing a transparent cathode covering the electron transporting layer;
S5, providing a second mask, and manufacturing a reflective cathode covering a portion of the transparent cathode with the second mask;
the reflective anode and the reflective cathode completely covering the light emitting layer, together, and the reflective anode and the reflective cathode partially overlap at most in a vertical direction perpendicular to the array substrate;
S6, implementing package on the transparent cathode and the reflective cathode to manufacture a package layer covering the transparent cathode and the reflective cathode.

7. The manufacture method of the double side OLED display element according to claim 6, wherein the transparent anode utilizes a material having a high transmission rate, a high conductivity and a high work function; the reflective anode utilizes a material having a high reflectivity, a high conductivity and a high work function.

8. The manufacture method of the double side OLED display element according to claim 7, wherein a material utilized for the transparent anode is indium tin oxide, indium zinc oxide, aluminum doped zinc oxide or indium zinc tin oxide; a material utilized for the reflective anode is silver, gold or platinum.

9. The manufacture method of the double side OLED display element according to claim 6, wherein the transparent cathode utilizes a material having a high transmission rate, a high conductivity and a low work function; the reflective cathode utilizes a material having a high reflectivity, a high conductivity and a low work function.

10. The manufacture method of the double side OLED display element according to claim 9, wherein a material utilized for the transparent cathode is lanthanum hexaboride, or a stack combination of magnesium and silver; a material utilized for the reflective cathode is aluminum or magnesium.

11. A manufacture method of a double side OLED display element, comprising steps of:
S1, providing an array substrate, and manufacturing a transparent anode covering the array substrate;
S2, providing a first mask, and manufacturing a reflective anode covering a portion of the transparent anode with the first mask;
S3, sequentially manufacturing a hole transporting layer covering the reflective anode and the transparent anode, a light emitting layer covering the hole transporting layer and an electron transporting layer covering the light emitting layer;
S4, manufacturing a transparent cathode covering the electron transporting layer;
S5, providing a second mask, and manufacturing a reflective cathode covering a portion of the transparent cathode with the second mask;
the reflective anode and the reflective cathode completely covering the light emitting layer, together, and the reflective anode and the reflective cathode partially overlap at most in a vertical direction perpendicular to the array substrate;
S6, implementing package on the transparent cathode and the reflective cathode to manufacture a package layer covering the transparent cathode and the reflective cathode;
wherein the transparent anode utilizes a material having a high transmission rate, a high conductivity and a high work function; the reflective anode utilizes a material having a high reflectivity, a high conductivity and a high work function;
wherein the transparent cathode utilizes a material having a high transmission rate, a high conductivity and a low work function; the reflective cathode utilizes a material having a high reflectivity, a high conductivity and a low work function.

12. The manufacture method of the double side OLED display element according to claim 11, wherein a material utilized for the transparent anode is indium tin oxide, indium zinc oxide, aluminum doped zinc oxide or indium zinc tin oxide; a material utilized for the reflective anode is silver, gold or platinum.

13. The manufacture method of the double side OLED display element according to claim 11, wherein a material utilized for the transparent cathode is lanthanum hexaboride, or a stack combination of magnesium and silver; a material utilized for the reflective cathode is aluminum or magnesium.
